(19) United States
(12) Patent Application Publication
(10) Pub. No.: US 2025/0374703 A1
(43) Pub. Date: Dec. 4, 2025

(54) IMAGE SENSOR

(71) Applicant: Taiwan Semiconductor Manufacturing Company, Ltd., Hsinchu (TW)

(72) Inventors: Feng-Chien HSIEH, Hsinchu (TW); Wei-Li HU, Hsinchu (TW); Chien-Nan TU, Hsinchu (TW)

(73) Assignee: Taiwan Semiconductor Manufacturing Company, Ltd., Hsinchu (TW)

(21) Appl. No.: 18/733,634

(22) Filed: Jun. 4, 2024

(51) Int. Cl. H01L 27/146

(52) U.S. Cl. CPC H10F 39/813; H10F 39/182; H10F 39/8027; H10F 39/8053

(57) ABSTRACT

An image sensor includes a plurality of photodetectors, a plurality of optical filters, a grid structure and a single round source follower transistor. The photodetectors are disposed on a semiconductor substrate. The optical filters respectively cover at least one of the photodetectors. The grid structure is disposed on the semiconductor substrate and laterally surrounds the optical filters. The grid structure includes a plurality of first elongated grid sections and second elongated grid sections, the first elongated grid sections are arranged parallel to each other and extend in a first direction, the second elongated grid sections are arranged parallel to each other and extend in a second direction, the first and second elongated grid sections intersect each other at intersection points and define at least one closed opening extending in a vertical direction through the intersection points. The single round source follower transistor is disposed in the closed opening.

### BACKGROUND

Many modern-day electronic devices (e.g., digital cameras, optical imaging devices, etc.) comprise image sensors. An image sensor comprises an array of pixel areas, and each pixel area contains a photodetector configured to capture optical signals (e.g., light) and convert it to digital data (e.g., a digital image). Complementary metal-oxide-semiconductor (CMOS) image sensors are often used over charge-coupled device (CCD) image sensors because of their many advantages, such as lower power consumption, faster data processing, and lower manufacturing costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic cross-sectional view of an image sensor according to an embodiment of the present disclosure.

FIGS. 2A to 2C respectively illustrate a top view of an image sensor according to an embodiment of the present disclosure.

FIGS. 3A to 3C respectively illustrate a top view of an image sensor according to another embodiment of the present disclosure.

FIGS. 4A and 4B respectively illustrate a top view of an image sensor according to an embodiment of the present disclosure.

FIGS. 5A to 5C illustrate a top view of the lens disposed above the image sensor.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure relates to an image sensor used in electronic devices (e.g., digital cameras, optical imaging devices, etc.). The image sensor converts optical images into digital data that can be represented as digital images. The image sensor includes an array of pixel sensors, which are unit devices used to convert optical images into digital data. Some types of pixel sensors include charge-coupled device (CCD) image sensors and complementary metal-oxide-semiconductor (CMOS) image sensors. Compared with CCD pixel sensors, CMOS pixel sensors are favored due to their low power consumption, small size, fast data processing speed, direct data output, and low manufacturing cost.

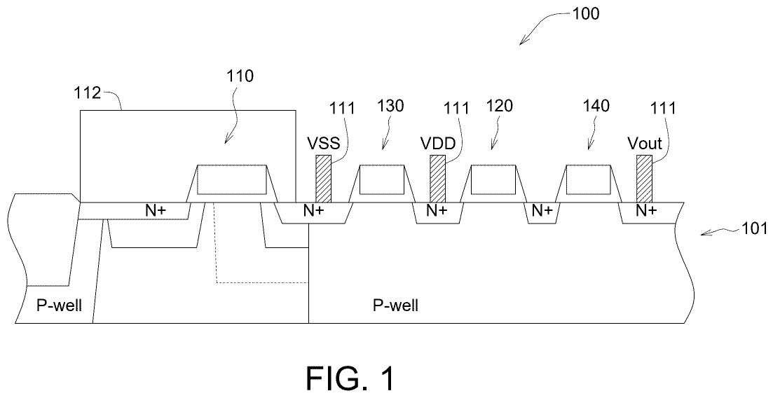

Referring to FIG. 1, a schematic cross-sectional view of an image sensor 100 according to an embodiment of the present disclosure is illustrated. In one embodiment, the image sensor 100 includes a plurality of photodetectors 110 (only one is shown) disposed in a device area of a semiconductor substrate 101. The photodetectors 110 are configured to absorb incident radiation (e.g., photons) and generate corresponding electrical signals corresponding to the incident radiation. In some embodiments, the photodetectors 110 are arranged in an array of photodetectors 110 including multiple rows and multiple columns. The semiconductor substrate 101 includes any type of semiconductor body (e.g., monocrystalline silicon/CMOS blocks, germanium (Ge), silicon germanium (SiGe), III-V semiconductors, silicon on insulator (SOI), etc.).

In addition, some pixel devices (for example, source follower transistors 120, reset transistors 130, and row selection transistors 140, etc.), source/drain contacts 111 for transmitting signals VSS, VDD, and Vout and interconnection structures thereof are arranged along a first surface (e.g., front side surface) of the semiconductor substrate 101 is provided. The pixel device may be electrically coupled to the photodetectors 110 through interconnect structures. In some embodiments, a transistor includes source/drain regions, a gate structure, and spacers on the sidewalls of the gate structure. The gate structure may include a gate dielectric layer and a gate electrode on the gate dielectric layer. The transistors 120, 130 and 140 can be electrically coupled to vias (or contacts 111) and conductive lines in the interconnect structures. In some embodiments, a capacitor structure (not shown) may be electrically coupled to the photodetectors 110 and/or the transistors 120, 130 and 140. In this case, the capacitor structure can be used as a decoupling capacitor to reduce noise and coupling interference of the image sensor 100.

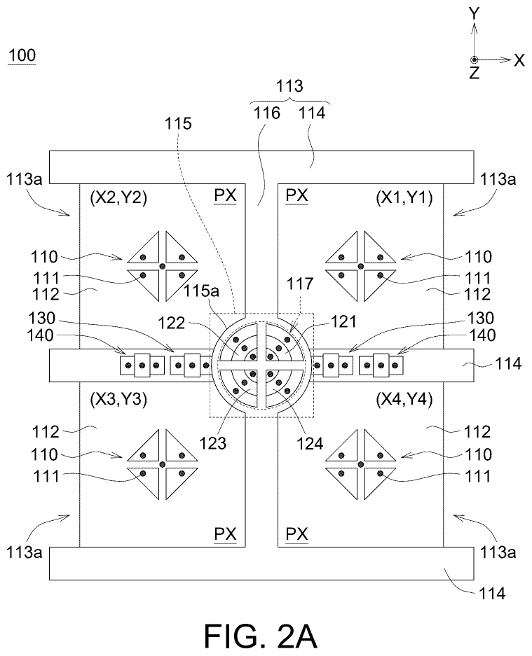

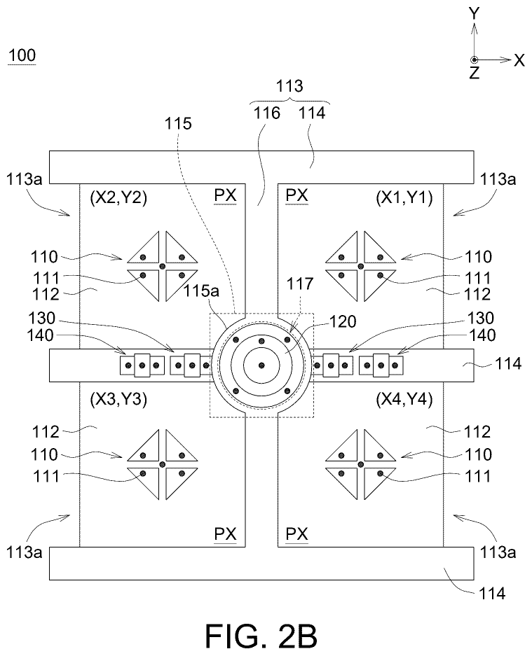

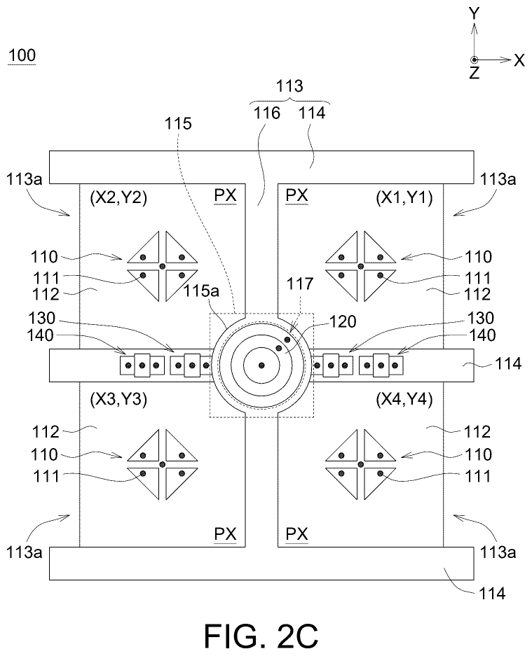

In addition, a plurality of optical filters 112 is provided on the semiconductor substrate 101 and the photodetectors 110. The optical filters 112 are arranged in an array of pixel areas PX including a plurality of rows and a plurality of columns, as shown in FIGS. 2A and 2B. In some embodiments, each of the optical filters 112 covers at least one of the photodetectors 110 and is corresponding to at least one of the photodetectors 110. The optical filters 112 are configured to transmit light having a specific wavelength (or a specific range of wavelengths). For example, the first optical filter 112 is configured to transmit light having a wavelength in a first range (e.g., photons of visible light wavelengths or invisible light wavelengths) and the second optical filter 112 is configured to transmit light having a wavelength in a second range that is different from the first range, and the third optical filter 112 is configured to transmit a light having wavelengths in a third range that is different from the first range and the second range. In some embodiments, the plurality of optical filters 112 may be color filters. For example, the first optical filter 112 may be a red filter, the second optical filter 112 may be a green filter, and the third optical filter 112 may be a blue filter. In some embodiments, the optical filters 112 may be IR filters configured to filter incident radiation having infrared (IR) wavelengths. In still other embodiments, the optical filters 112 may include a combination of color filters and/or IR filters.

The optical filters 112 include filter materials. In some embodiments, the filter material is or includes, for example, a photoresist (e.g., positive photoresist/negative photoresist) containing dyes/pigments, dispersant polymers, polymerized monomers, and/or other chemical substances (e.g., those used in polymerization reactions).

Furthermore, referring to FIGS. 2A and 2B, top views of the image sensor 100 according to an embodiment of the present disclosure are respectively illustrated. The grid structure 113 is disposed on the first surface of the semiconductor substrate and laterally surrounds the photodetectors 110 and the optical filters 112. The grid structure 113 is or contains a dielectric material. For example, the grid structure 113 may be or include, for example, an oxide (e.g., silicon dioxide (SiO₂)), a nitride (e.g., silicon nitride (SiN)), an oxynitride (e.g., silicon oxynitride (SiO_{X}N_{Y})) etc. In some embodiments, the filter material has a first refractive index, and the dielectric material of the grid structure 113 has a second refractive index that is less than the first refractive index. In yet other embodiments, the dielectric material is a low refractive index (low-n) material (e.g., a material having a refractive index of less than about 1.5).

The grid structure 113 includes a plurality of first elongated grid sections 114 and a plurality of second elongated grid sections 116. The first elongated grid sections 114 are arranged parallel to each other and each extends in a first direction (e.g., the X-axis direction). The second elongated grid sections 116 are arranged parallel to each other and each extends in a second direction orthogonal to the first direction (e.g., the Y-axis direction). The first elongated grid sections 114 intersect with the second elongated grid section 116 and define a plurality of grid openings 113a extending through the grid structure 113. Each grid opening 113a is located directly above at least one photodetector 110 of the plurality of photodetectors 110, and a plurality of optical filters 112 are disposed within the grid opening 113a. The grid structure 113 is configured to increase sensitivity and reduce cross-talk between adjacent photodetectors 110, for example, to increase the quantum efficiency (QE) of the photodetectors 110.

Referring to FIG. 2A, the first elongated grid sections 114 and the second elongated grid sections 116 intersect each other at a plurality of intersection points 115 (as indicated by the dotted line) and define a closed opening 117 (as indicated by the dotted line) extending in the vertical direction through at least one of the intersection points 115. As shown in FIG. 2A, four filters 112 are disposed in four grid openings 113a to form four separate pixel areas PX, and a pixel unit surrounded by the four pixel areas PX has a closed opening 117 located in the center of the pixel unit. Each partition wall 115a defined by the closed opening 117 laterally surrounds one or more source follower transistors 120, and the one or more source follower transistors 120 are disposed within a corresponding closed opening 117.

As shown in FIG. 2A, the partition wall 115a is formed between the closed opening 117 and the corresponding grid opening 113a. This partition wall 115a protrudes from the closed opening 117 to the adjacent grid opening 113a and has an arc side surface in the vertical direction, but it is not limited thereto. In some embodiments, intersection points 115 has a circle shape or other shape, and the closed opening 117 has a circular, square or other geometric footprint at the intersections 115, and the source follower transistors 120 disposed at the intersection 115 may, for example, have the same layout as the closed opening. 117 (e.g., having the same footprint).

In one embodiment, each of the grid openings 113a has a rectangular shape with an arc corner. That is, the grid opening 113a is not a traditional rectangular shape or a square shape, and the optical filters 112 disposed within the grid openings 113a may have the same occupied area or shape as the grid opening 113a (for example, having a rectangular shape with an arc corner).

As shown in FIG. 2A, each pixel area PX has a plurality of photodetectors 110. The photodetectors 110 are coupled to the source follower transistors 120 disposed at the intersection points 115, and are close to each other to reduce noise interference. Taking four photodetectors 110 arranged in the same pixel area PX as an example, each photodetector 110 is configured to absorb incident radiation (for example, photons) and generate an electrical signal corresponding to the incident radiation. Relatively speaking, the greater the amount of incident radiation, the more electrical signals is generated to enhance quantum efficiency. But integrated chip technology is constantly improving, such improvements often involve scaling down device geometries to achieve lower manufacturing costs, higher component integration, higher speeds and better performance. Due to device scaling, the pixel areas PX of the image sensor 100 have smaller sizes and are closer to each other. However, as the size of the photodetectors 110 in the pixel area decreases, the number of incident photons reaching the photodetectors 110 is smaller. Therefore, the quantum efficiency (QE) of the pixel area is reduced, which may hinder the performance of the image sensor 100.

In this embodiment, the source follower transistors 120 are centrally arranged at the intersection point 115, and are changed from a linear arrangement to a circular arrangement to improve the integration degree. Compared with the traditional source follower transistors that are dispersed and linearly arranged in the grid structure 113 between pixel areas, the source follower transistors 120 in this embodiment have a centralized contact layout and it is convenient for the electrical signal to be output through the electrical connection structure disposed at the intersection point 115.

As shown in FIG. 2A, four source follower transistors 120 are disposed in the same closed opening 117, and each source follower transistor 120 is connected to four corresponding photodetectors 110 in the adjacent pixel area PX. For example, looking at the four quadrants divided by grid sections and regarding the intersection point 115 as the center point of coordinates, the first source follower transistor 121 located at the first corner is adjacent to the first pixel area PX in the first quadrant (X1, Y1). Next, the second source follower transistor 122 located in the second corner is adjacent to the second pixel area PX in the second quadrant (X2, Y2), and the third source follower transistor 123 located in the third corner is adjacent to the third pixel area PX in the third quadrant (X3, Y3), and the fourth source follower transistor 124 located in the fourth corner is adjacent to the pixel area PX in the fourth quadrant (X4, Y4). Each of the first to fourth source follower transistors 121-124 have a ¼ circular footprint in the same closed opening 117, and each of the source follower transistors 120 has an independent source contact 111, a drain contact and a gate contact for correspondingly receiving electrical signals from the four photodetectors 110 in the same pixel area PX.

As shown in FIG. 2B, a single common source follower transistor 120 is disposed in a closed opening 117, and the single common source follower transistor 120 is connected to sixteen photodetectors 110 in the adjacent four pixel areas PX. The single common source follower transistor 120 has a circular footprint and six contacts 111, which can reduce the number of contacts 111 compared to the number of contacts of the source follower transistors 120 divided into 4 in FIG. 2A. For example, in FIG. 2A, each of the four source follower transistors 120 independently provides with four source contacts 111, four drain contacts, and four gate contacts to receive the electrical signals of the four photodetectors 110 from each pixel area PX with a shorter response time, so that the signal transmission speed can be accelerated. However, in FIG. 2B, a single common source follower transistor 120 only needs to be provided with four source contacts, one drain contact and one gate contact, thus reducing the number of contacts 111. In FIG. 2B, the four source contacts are dispersed at the four corners and each corresponds to the four photodetectors 110 in the pixel areas PX near each corner, so as to correspondingly receive the electrical signals of the four photodetectors 110 from each pixel area PX. For example, the sixteen photodetectors 110 in the four pixel areas PX have a sequence of turning on or off. When the four photodetectors 110 in one of the four pixel areas PX are turned on, the twelve photodetectors 110 in the remaining three pixel areas PX are turned off until a period of cycle is completed. In this way, the single common source follower transistor 120 sequentially receives one set of electrical signals from four sets of electrical signals at a time, so the response time is longer and the signal transmission speed is slower.

As shown in FIGS. 2A and 2B, in some embodiments, four optical filters 112 of different colors respectively correspond to the pixel areas PX in the four quadrants. For example, the first pixel area PX in the first quadrant (X1, Y1) has a first color filter 112, the second pixel area PX in the second quadrant (X2, Y2) has a second color filter 112, and the third pixel area PX in the third quadrant (X3, Y3) has a third color filter 112, and the fourth pixel area PX in the fourth quadrant (X4, Y4) has a fourth color filter 112, where the first color, the second color, the third color and the fourth color can be one of the colors selected from red (R), blue (B), green (G) and white (W) respectively. The pixel areas PX in the four quadrants may form an image sensor 100 having four sub-pixel units of colors from R, G, B and W.

In addition, in FIG. 2C, four optical filters 112 of the same color respectively correspond to the pixel areas PX in the four quadrants. That is to say, the optical filters 112 can be one of red (R), blue (B), green (G) and white (W), and the pixel areas PX in the four quadrants can form an image sensor 100 having four sub-pixel units of a single color to increase the amount of light having a single color.

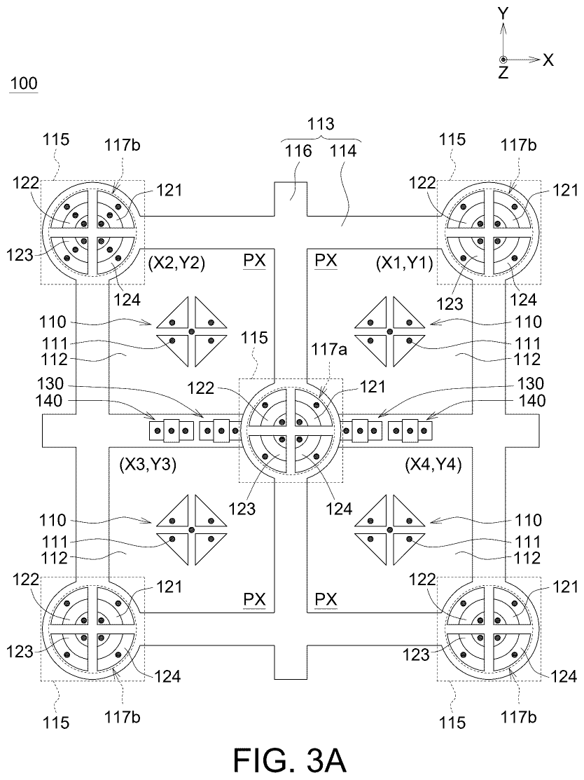

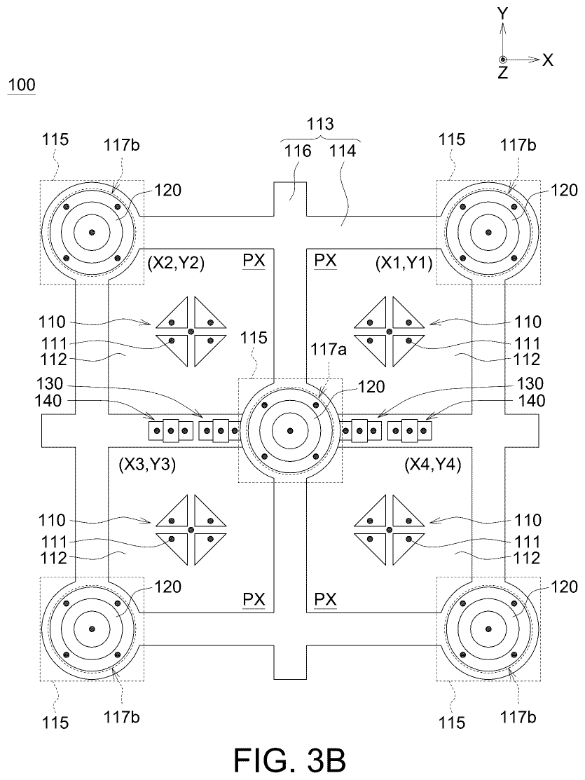

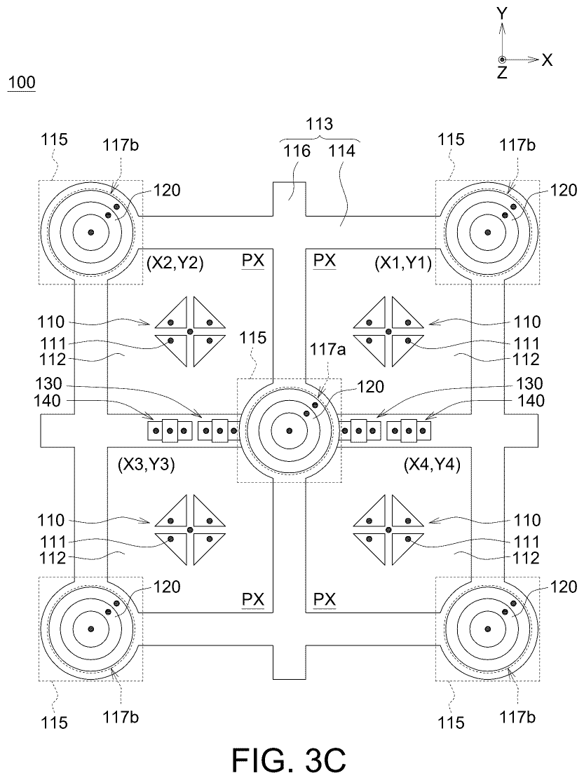

Referring to FIGS. 3A to 3C, top views of an image sensor 100 according to another embodiment of the present disclosure are respectively illustrated. In this embodiment, the image sensor 100 includes a plurality of photodetectors 110, a plurality of optical filters 112 and a grid structure 113. The optical filters 112 respectively cover at least one of the photodetectors 110. The grid structure 113 is disposed on the first surface of the semiconductor substrate 101 and laterally surrounds the photodetectors 110 and the optical filters 112. The grid structure 113 includes a plurality of first elongated grid sections 114 and a plurality of second elongated grid sections 116 that intersect at the intersection points 115. As mentioned above, the image sensor 100 in FIG. 3A is substantially similar to the image sensor 100 in FIG. 2A. The image sensor 100 in FIG. 3B is substantially similar to the image sensor 100 in FIG. 2B. The image sensor 100 in FIG. 3C is substantially similar to the image sensor 100 in FIG. 2C, and the same components are represented by the same or similar reference numbers. The image sensor 100 of this embodiment is different from the above-described embodiment in that the first elongated grid sections 114 and the second elongated grid sections 116 intersect at a plurality of intersection points 115 and define a central area closed opening 117 and a plurality of edge area closed openings 117 extending through the intersection points 115 in the vertical direction.

As shown in FIG. 3A, in one embodiment, four optical filters 112 are disposed in four grid openings 113a to form four separate pixel areas PX and a pixel unit surrounded by the four pixel areas PX has a central area closed opening 117a and four edge area closed openings 117b. The central area closed opening 117a is located in the center of the pixel unit, and the edge area closed openings 117b are located at the corner areas of the pixel unit. Each central area and edge area closing openings 117a and 117b laterally surrounds one or more source follower transistors 121-124, and one or more source follower transistors 121-124 are disposed in the corresponding central area closing opening 117a or the edge area closing openings 117b.

As shown in FIG. 3A, there is a first partition wall 115a between the central area closed opening 117a and a corresponding grid opening 113a. The first partition wall 115a protrudes from the central area closed opening 117 to the adjacent grid opening 113a and has a first arc side surface in the vertical direction, but it is not limited thereto. In addition, there is a second partition wall 115a between one of the edge area closed openings 117 and a corresponding grid opening 113a. The second partition wall 115a protrudes from the edge area closed opening 117 to the adjacent grid opening 113a in the vertical direction and has a second arc side surface, but it is not limited to thereto. The first arc side surface and the second arc side surface are respectively located on opposite sides of the corresponding grid opening 113a. For example, in some embodiments, the first arc side surface and the second arc side surface can be respectively located on opposite sides of the diagonal line of a corresponding grid opening 113a.

In some embodiments, each central area closed opening 117a or edge area closed opening 117b has a circular, square or other geometric footprint at the intersection point 115, and the source follower transistors 121-124 disposed at the intersection point 115 may, for example, have the same layout (e.g., having the same footprint) as the central or edge area closed openings 117a, 117b.

In one embodiment, the grid opening 113a has a rectangular shape with an arc corner. That is, the grid opening 113a is not a traditional rectangular shape or a square shape, and the optical filters 112 disposed within the grid openings 113a may have the same footprint or shape as the grid opening 113a (for example, having a rectangular shape with an arc corner).

As shown in FIG. 3A, there are four photodetectors 110 in each pixel area PX. These photodetectors 110 are coupled to the source follower transistors 121-124 disposed at the intersection point 115, and the source follower transistors 121-124 are close to each other to reduce noise interference. For example, four source follower transistors 121-124 are disposed in the same central area closed opening 117a, and sixteen other source follower transistors 121-124 are respectively disposed in four edge area closed openings 117b, and each of the source follower transistor 121-124 is coupled to two photodetectors 110 in the adjacent pixel area PX to increase the signal transmission speed. For example, each of the source follower transistors 121-124 located in the central area closed opening 117a receives electrical signals from two photodetectors 110 in the same pixel area PX, while each of source follower transistor 121-124 located in the edge area closed opening 117b receives electrical signals from another two photodetectors 110 in the same pixel area PX. Compared with the arrangement in FIG. 2A, the arrangement in FIG. 3A can increase the signal transmission speed by two times.

As shown in FIG. 3B, a single common source follower transistor 120 is disposed in a central area closed opening 117a and four common source follower transistors 120 are respectively disposed in four edge area closed openings 117b, and each of the common source follower transistors 120 is coupled to eight photodetectors 110 in adjacent four pixel areas PX. For example, the sixteen photodetectors 110 in the four pixel areas PX have a sequence of turning on or off. When the four photodetectors 110 in one of the pixel areas PX are turned on, the twelve photodetectors 110 in the remaining three pixel areas PX are turned off until one period of cycle is completed. In this way, the common source follower transistor 120 sequentially receives one set of electrical signals from four sets of electrical signals at a time. Therefore, in the same timing sequence, the source follower transistor 120 located in the central area closed opening 117a receives electrical signals from two photodetectors 110 in the same pixel area PX, while the source follower transistor 120 located in the edge area closed openings 117b receives electrical signals from another two photodetectors 110 in the same pixel area PX. Each source follower transistor 120 receives electrical signals from the other two photodetectors 110 in the same pixel area PX. Compared with the arrangement in FIG. 2B, the arrangement in FIG. 3B can increase the signal transmission speed by two times.

As shown in FIGS. 3A and 3B, in some embodiments, four optical filters 112 of different colors respectively correspond to the pixel areas PX in the four quadrants. That is to say, the four optical filters 112 may have one of colors selected from red (R), blue (B), green (G), and white (W), respectively. The pixel areas PX in the four quadrants may form an image sensor 100 having four sub-pixel units of colors from R, G, B and W.

In addition, in FIG. 3C, four optical filters 112 of the same color respectively correspond to the pixel areas PX in the four quadrants. That is to say, the optical filters 112 can be one of red (R), blue (B), green (G) and white (W), and the pixel areas PX in these four quadrants can form an image sensor 100 having four sub-pixel units of a single color to increase the amount of light having a single color.

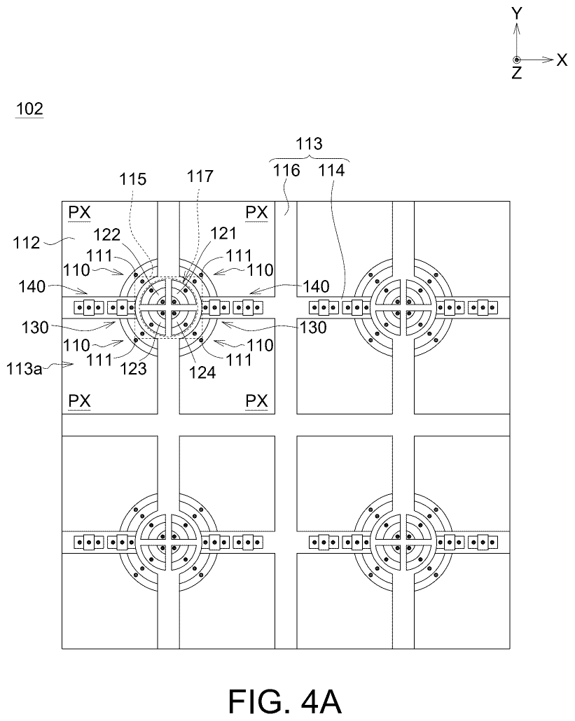

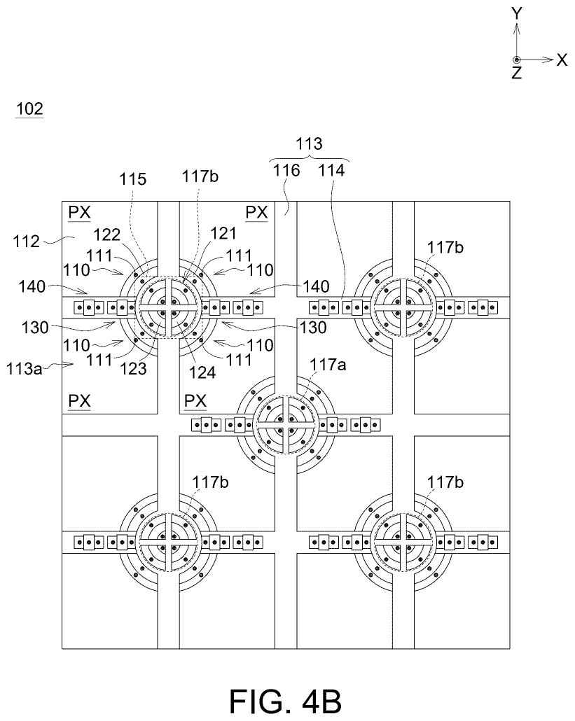

Referring to FIGS. 4A and 4B, top views of an image sensor 102 according to an embodiment of the present disclosure are respectively illustrated. In this embodiment, the image sensor 102 includes a plurality of photodetectors 110, a plurality of optical filters 112 and a grid structure 113. As mentioned above, the image sensor 100 in FIG. 4A is substantially similar to the image sensor 100 in FIG. 2A. The image sensor 100 in FIG. 4B is substantially similar to the image sensor 100 in FIG. 3A, and the same components are represented by the same or similar reference numbers. The image sensor 100 of this embodiment is different from the above-described embodiments in that a plurality of source follower transistors 121-124 are respectively disposed in the closed openings 117, and the photodetectors 110 laterally surround the source follower transistors 121-124.

As shown in FIG. 4A, four optical filters 112 are disposed in four grid openings 113a to form four separate pixel areas PX, and a pixel unit surrounded by the four pixel areas PX has a closed opening 117 (shown in dashed lines) located in the center of the pixel unit. The closed opening 117 laterally surrounds one or more source follower transistors 121-124, and the one or more source follower transistors 121-124 are disposed within the corresponding closed opening 117.

As shown in FIG. 4A, each pixel area PX has a photodetector 110. Each photodetector 110 is coupled to one of the source follower transistors 121-124 disposed at the same intersection point 115 and surrounds one of the source follower transistors 121-124 laterally. The source follower transistors 121-124 are close to reduce noise interference. Compared with FIGS. 2A and 3A, the photodetectors 110 and the source follower transistors 120 of this embodiment match in shape and are arranged in a concentric circle near the intersection point 115, which has a centralized contact layout and facilitates the electrical signal to be output via the electrical connection structure disposed at the intersection point 115.

As shown in FIG. 4A, four source follower transistors 120 are disposed in the same closed opening 117, and each source follower transistor 120 is connected to four photodetectors 110 in the adjacent pixel areas PX. Compared with the traditional photodetector arranged in the center of each pixel area PX, the photodetectors 110 in this embodiment are arranged in the corner area of each pixel area PX (or optical filters 112) and concentrated near the intersection point 115, so that the signal transmission speed is increased and the noise interference is reduced.

In addition, in FIG. 4B, four source follower transistors 121-124 are disposed in the same central area closed opening 117a, and another sixteen source follower transistors 120 are respectively disposed in four edge area closed openings 170b, each of the source follower transistors 121-124 is coupled to a photodetector 110 in the adjacent pixel area PX to increase the signal transmission speed. For example, each of source follower transistors 121-124 located in the central area closed opening 117 correspondingly receives an electrical signal from a photodetector 110 in the same pixel area PX, and each of the source follower transistors 121-124 located in the edge area closed opening 117 correspondingly receives an electrical signal from another photodetector 110 in the same pixel area PX. The two photodetectors 110 are located at two corner areas of the same pixel area PX and are located in the diagonal direction. Compared with the configuration in FIG. 4A, the configuration in FIG. 4B can increase the signal transmission speed by two times.

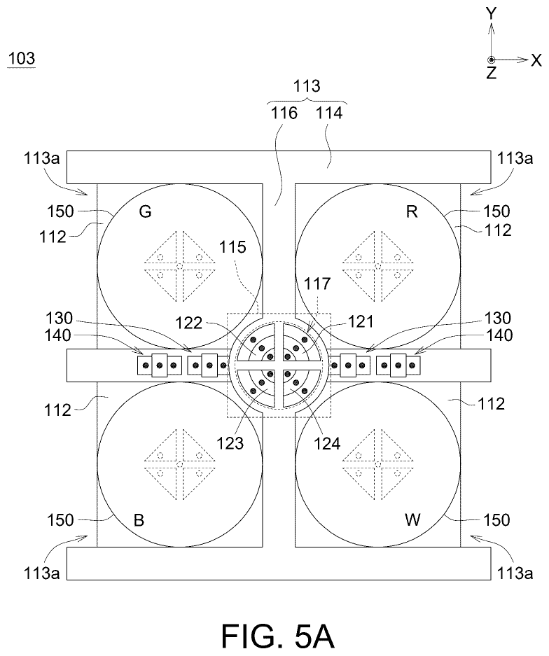

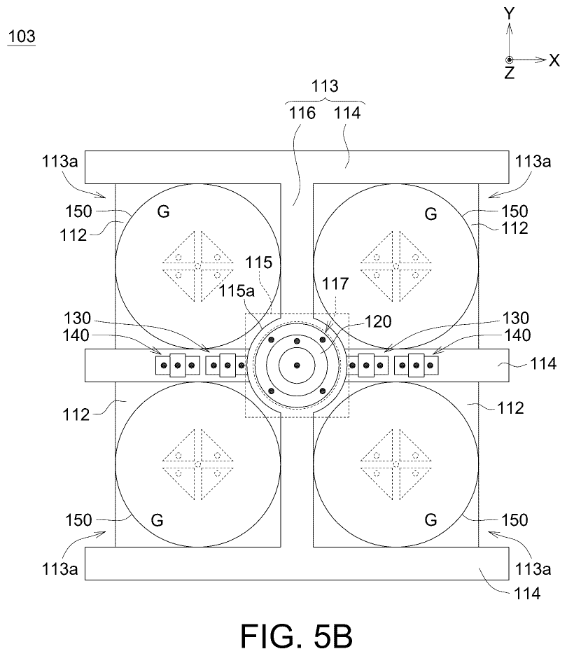

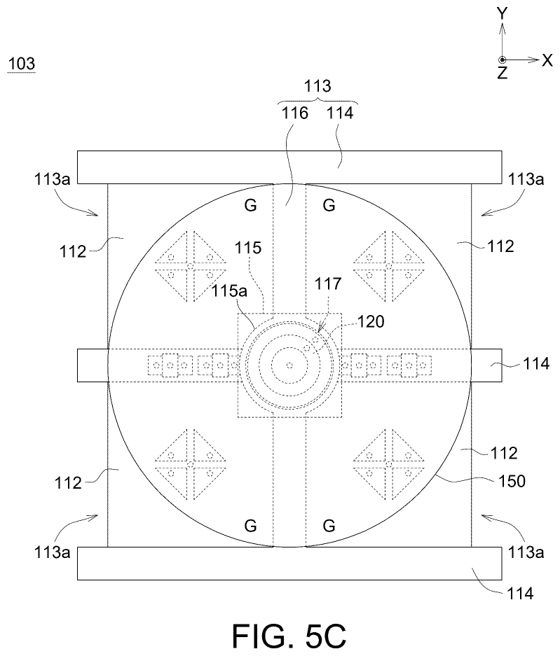

Referring to FIG. 5A, a top view of four lenses 150 disposed above the image sensor 103 is illustrated. In one embodiment, four lenses 150 are respectively disposed above four optical filters 112 of different colors and correspond to the pixel areas PX located in the four quadrants. The image sensor 103 in this embodiment may be the image sensor 100, 102 shown in FIG. 2A, 3A or 4A. That is to say, the four optical filters 112 may have one of colors of red (R), blue (B), green (G), and white (W), respectively. The pixel areas PX in the four quadrants can form an image sensor 103 having four sub-pixel units of colors from R, G, B and W, and each of the four optical filters 112 has a lens 150 to enhance the light intensity of each color.

Referring to FIG. 5B, a top view of four lenses 150 disposed above the image sensor 103 is illustrated. In one embodiment, four lenses 150 are respectively disposed above four optical filters 112 of same colors and correspond to the pixel areas PX located in the four quadrants. The image sensor 100 in this embodiment may be the image sensor 100 shown in FIG. 2B, 3B or 4B. That is to say, the four optical filters 112 may have one of colors of red (R), blue (B), green (G), and white (W). The pixel areas PX in the four quadrants can form an image sensor 103 having four sub-pixel units of a single color, and each of the four optical filters 112 has a lens 150 to enhance the light intensity of a single color.

Referring to FIG. 5C, a top view of a single lens 150 disposed above the image sensor 103 is illustrated. In one embodiment, a single lens 150 is disposed above four optical filters 112 of the same color and corresponds to the pixel areas PX located in four quadrants. The image sensor 100 in this embodiment may be the image sensor 100 shown in FIGS. 2C and 3C. That is to say, the optical filters 112 can be one of red (R), blue (B), green (G) and white (W). The pixel areas PX in the four quadrants can form an image sensor 103 having four sub-pixel units of a single color, and the four optical filters 112 share a single lens 150 to increase the light intensity of a single color.

The present disclosure is directed to an image sensor with round source follower transistors. The image sensor with round source follower transistors is arranged as quad phase detector (QPD) with four pixel areas located in the four quadrants. The round source follower transistors are disposed within a corresponding closed opening of the intersection points defined by the first elongated grid sections and the second elongated grid sections of the grid structure. Compared with the traditional source follower transistors that are dispersed and linearly arranged in the grid structure between pixel areas, the source follower transistors in this disclosure have a centralized contact layout and it is convenient for the electrical signal to be output through the electrical connection structure disposed at the intersection point, so that the signal transmission speed is increased and the noise interference is reduced.

According to some embodiments of the present disclosure, an image sensor includes a plurality of photodetectors, a plurality of optical filters, a grid structure and a single round source follower transistor. The plurality of photodetectors is disposed on a semiconductor substrate. The plurality of optical filters respectively covers at least one of the photodetectors. The grid structure is disposed on the semiconductor substrate, and the grid structure laterally surrounds the optical filters, wherein the grid structure comprises a plurality of first elongated grid sections and a plurality of second elongated grid sections, the first elongated grid sections are arranged parallel to each other and extend in a first direction, the second elongated grid sections are arranged parallel to each other and extend in a second direction, the first elongated grid sections and the second elongated grid sections intersect each other at a plurality of intersection points and define at least one closed opening extending in a vertical direction through the intersection points. The single round source follower transistor is disposed in the closed opening.

According to some embodiments of the present disclosure, an image sensor includes a plurality of photodetectors, a plurality of optical filters, a grid structure and a plurality of source follower transistors. The plurality of photodetectors is disposed on a semiconductor substrate. The plurality of optical filters respectively covers at least one of the photodetectors. The grid structure is disposed on the semiconductor substrate, and the grid structure laterally surrounds the optical filters, wherein the grid structure comprises a plurality of first elongated grid sections and a plurality of second elongated grid sections, the first elongated grid sections are arranged parallel to each other and extend in a first direction, the second elongated grid sections are arranged parallel to each other and extend in a second direction, the first elongated grid sections and the second elongated grid sections intersect each other at a plurality of intersection points and define a central area closed opening and a plurality of edge area closed openings extending in a vertical direction through the intersection points. The plurality of source follower transistors is respectively disposed in the central area closed opening and the edge area closed openings.

According to some embodiments of the present disclosure, an image sensor includes a plurality of photodetectors, a plurality of optical filters, a grid structure and a plurality of source follower transistors. The plurality of photodetectors is disposed on a semiconductor substrate. The plurality of optical filters respectively covers at least one of the photodetectors. The grid structure is disposed on the semiconductor substrate, and the grid structure laterally surrounds the optical filters, wherein the grid structure comprises a plurality of first elongated grid sections and a plurality of second elongated grid sections, the first elongated grid sections are arranged parallel to each other and extend in a first direction, the second elongated grid sections are arranged parallel to each other and extend in a second direction, the first elongated grid sections and the second elongated grid sections intersect each other at a plurality of intersection points and define a plurality of closed openings extending in a vertical direction through the intersection points. The plurality of source follower transistors is respectively disposed in the closed openings, and the photodetectors surround the source follower transistors laterally.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An image sensor, comprising:
a plurality of photodetectors disposed on a semiconductor substrate;
a plurality of optical filters respectively covering at least one of the photodetectors;
a grid structure disposed on the semiconductor substrate, the grid structure laterally surrounding the optical filters, wherein the grid structure comprises a plurality of first elongated grid sections and a plurality of second elongated grid sections, the first elongated grid sections are arranged parallel to each other and extend in a first direction, the second elongated grid sections are arranged parallel to each other and extend in a second direction, the first elongated grid sections and the second elongated grid sections intersect each other at a plurality of intersection points and define at least one closed opening extending in a vertical direction through the intersection points; and
a single round source follower transistor disposed in the closed opening.

2. The image sensor of claim 1, wherein the intersection point has a circle shape.

3. The image sensor of claim 1, wherein the closed opening is a circular opening.

4. The image sensor of claim 1, wherein the first elongated grid sections intersect with the second elongated grid sections and define a plurality of grid openings extending through the grid structure.

5. The image sensor of claim 4, wherein each of the optical filters is disposed in a corresponding one of the grid openings.

6. The image sensor of claim 4, wherein a partition wall is arranged between one of the closed openings and a corresponding one of grid openings, and the partition wall protrudes from the closed opening to the corresponding grid opening and has an arc side surface in the vertical direction.

7. The image sensor of claim 4, wherein each of the grid openings has a rectangular shape with an arc corner.

8. The image sensor of claim 1, wherein the photodetectors share the single round source follower transistor.

9. An image sensor, comprising:
a plurality of photodetectors disposed on a semiconductor substrate;
a plurality of optical filters respectively covering at least one of the photodetectors;
a grid structure disposed on the semiconductor substrate, the grid structure laterally surrounding the optical filters, wherein the grid structure comprises a plurality of first elongated grid sections and a plurality of second elongated grid sections, the first elongated grid sections are arranged parallel to each other and extend in a first direction, the second elongated grid sections are arranged parallel to each other and extend in a second direction, the first elongated grid sections and the second elongated grid sections intersect each other at a plurality of intersection points and define a central area closed opening and a plurality of edge area closed openings extending in a vertical direction through the intersection points; and
a plurality of source follower transistors respectively disposed in the central area closed opening and the edge area closed openings.

10. The image sensor of claim 9, wherein the intersection point has a circle shape.

11. The image sensor of claim 9, wherein the central area closed opening is a circular opening, and the edge area closed openings are circular openings.

12. The image sensor of claim 9, wherein the first elongated grid sections intersect the second elongated grid sections and define a plurality of grid openings extending through the grid structure.

13. The image sensor of claim 12, wherein each of the optical filters is disposed in a corresponding one of the grid openings.

14. The image sensor of claim 12, wherein a partition wall is arranged between one of the closed openings and a corresponding one of grid openings, and the partition wall protrudes from the closed opening to the corresponding grid opening and has an arc side surface in the vertical direction.

15. The image sensor of claim 12, wherein each of the grid openings has a rectangular shape with an arc corner.

16. The image sensor of claim 9, wherein the photodetectors share a single round source follower transistor among the plurality of source follower transistors.

17. An image sensor, comprising:
a plurality of photodetectors disposed on a semiconductor substrate;
a plurality of optical filters respectively covering at least one of the photodetectors;
a grid structure disposed on the semiconductor substrate, the grid structure laterally surrounding the optical filters, wherein the grid structure comprises a plurality of first elongated grid sections and a plurality of second elongated grid sections, the first elongated grid sections are arranged parallel to each other and extend in a first direction, the second elongated grid sections are arranged parallel to each other and extend in a second direction, the first elongated grid sections and the second elongated grid sections intersect each other at a plurality of intersection points and define a plurality of closed openings extending in a vertical direction through the intersection points; and
a plurality of source follower transistors respectively disposed in the closed openings, and the photodetectors surround the source follower transistors laterally.

18. The image sensor of claim 17, wherein the photodetectors are arranged in a circle.

19. The image sensor of claim 17, wherein the photodetectors and the source follower transistors match in shape and are arranged in a concentric circle near each of the intersection points.

20. The image sensor of claim 17, wherein the photodetectors are correspondingly disposed in corner areas of the optical filters.
